(19) United States
(12) Patent Application Publication
(10) Pub. No.: US 2021/0043508 A1
(43) Pub. Date: Feb. 11, 2021

(54) METHOD OF MANUFACTURING VIAS CROSSING A SUBSTRATE

(71) Applicant: Commissariat à l'Énergie Atomique et aux Énergies Alternatives, Paris (FR)

(72) Inventor: Gabriel Pares, Grenoble (FR)

(73) Assignee: Commissariat à l'Énergie Atomique et aux Énergies Alternatives, Paris (FR)

(21) Appl. No.: 16/987,865

(22) Filed: Aug. 7, 2020

(30) Foreign Application Priority Data
Aug. 9, 2019 (FR) 1909113

(51) Int. Cl. H01L 21/768

(52) U.S. Cl. CPC H01L 21/76871

(57) ABSTRACT

A method of manufacturing at least one element crossing a substrate, including a step of electrodeposition of at least a portion of said element in an opening crossing the substrate and on a portion of a conductive seed layer located on said at least a portion of a surface of the substrate, said seed layer portion being located on a same side of the opening as said surface of the substrate.

This application claims the priority benefit of French patent application number FR19/09113, the content of which is hereby incorporated by reference in its entirety to the maximum extent allowable by law.

### TECHNICAL BACKGROUND

The present disclosure generally concerns electronic devices, and more particularly a device comprising a substrate crossed by conductive vias of connection between electronic circuits.

### PRIOR ART

An electronic integrated circuit chip is defined by a substrate and by elements located on a surface, called front side, of the substrate. Among such elements, the chip comprises electronic circuits formed by components such as transistors, resistors, diodes, capacitors, etc., and by electrically-conductive links between the components. One or a plurality of electronic chips may be arranged in an integrated circuit package. Such a package typically comprises pins intended to be connected, for example, welded or soldered, to a device such as a PCB-type printed circuit board.

To electrically couple the electronic circuits of the chips to one another and/or to conductive structures such as the pins of the package, electric connections by conductive vias crossing the substrate of the chips and/or conductive vias crossing one or a plurality of substrates other than those of the chips may be provided.

### SUMMARY

There is a need to have a method of forming a substrate crossed by vias having, as compared with current substrates, a higher number of vias per surface area unit.

There is a need to have a via forming method simpler to implement and/or faster than current methods.

An embodiment overcomes all or part of the disadvantages of known via forming methods.

An embodiment provides a method of manufacturing at least one element crossing a substrate, comprising a step of electrodeposition of at least part of said element in an opening crossing the substrate and on a portion of a conductive seed layer located on at least part of a surface of the substrate, said seed layer portion being located on a same side of the opening as said surface of the substrate.

According to an embodiment, the openings have a form factor greater than 10.

According to an embodiment, the seed layer and the substrate are assembled on a support and the conductive seed layer is located between the substrate and a support.

According to an embodiment, a first additional layer located between the support and the seed layer is capable of causing a lighter adhesion of the seed layer to the support than to the substrate.

According to an embodiment, a first additional etch stop layer of the support is located between the support and the seed layer.

According to an embodiment, a second additional adhesion layer of the seed layer is located between the seed layer and the first additional layer.

According to an embodiment, the seed layer and the support are separated by an electric insulator.

According to an embodiment, the support and the seed layer extend laterally beyond the substrate.

According to an embodiment, the walls of the opening are covered with an insulating layer.

According to an embodiment, said insulating layer is formed by thermal oxidation.

According to an embodiment, the method comprises a step of forming of blind cavities in a wafer comprising the future substrate, and a step of removal of a portion of the wafer comprising the bottoms of the cavities.

According to an embodiment, a portion of said insulating layer covering said bottoms of the cavities is left in place at the removal step, another insulating layer is deposited on another surface of the substrate opposite to said surface, and said portion is then removed.

According to an embodiment, an additional seed layer in contact with said seed layer covers at least part of the walls of the openings.

According to an embodiment, the method comprises a step of forming another seed layer on said other insulating layer or on another surface of the substrate opposite to said surface.

According to an embodiment, the electrodeposition step comprises the forming of a solder bump on the crossing element.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a simplified cross-section view showing an example of a device to which the described embodiments apply;

FIG. 2 is a simplified cross-section view showing another example of a device to which the described embodiments apply;

FIG. 3 is a simplified cross-section view showing a step of an embodiment of a method of manufacturing one or a plurality of conductive elements crossing a substrate;

FIG. 4 is a simplified cross-section view showing another step of the method;

FIG. 5 is a simplified cross-section view showing another step of the method;

FIG. 6 is a partial simplified cross-section view showing an embodiment of an element of the structure obtained at the step of FIG. 3;

FIG. 7 is a simplified cross-section view showing a step of a first embodiment of the step of FIG. 3;

FIG. 8 is a simplified cross-section view showing another step of the first embodiment;

FIG. 9 is a simplified cross-section view showing another step of the first embodiment;

FIG. 10 is a simplified cross-section view showing a step of a second embodiment of the step of FIG. 3;

FIG. 11 is a simplified cross-section view showing another step of the second embodiment;

FIG. 12 is a simplified cross-section view showing another step of the second embodiment;

FIG. 13 is a simplified cross-section view showing another step of the second embodiment;

FIG. 14 is a simplified cross-section view showing another step of the second embodiment;

FIG. 15 is a simplified cross-section view showing a third embodiment of the step of FIG. 3;

FIG. 16 is a simplified cross-section view showing a step of a fourth embodiment of the step of FIG. 3;

FIG. 17 is a simplified cross-section view showing another step of the fourth embodiment;

FIG. 18 is a simplified cross-section view showing a step of a fifth embodiment of the step of FIG. 3;

FIG. 19 is a simplified cross-section view showing a step similar to that of FIG. 4 after the implementation of the fifth embodiment; and

FIG. 20 is a simplified cross-section view showing a variant of the step of FIG. 5.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, electronic integrated circuit chips and their electronic circuits are not described in detail, the described embodiments being compatible with usual integrated circuit chips.

Unless specified otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “top”, “bottom”, “left”, “right”, etc., or relative positions, such as terms “above”, “under”, “upper”, “lower”, etc., or to terms qualifying directions, such as terms “horizontal”, “vertical”, etc., unless otherwise indicated, it is referred to the orientation of the drawings.

Unless specified otherwise, the expressions “around”, “approximately”, “substantially” and “in the order of” signify within 10%, and preferably within 5%.

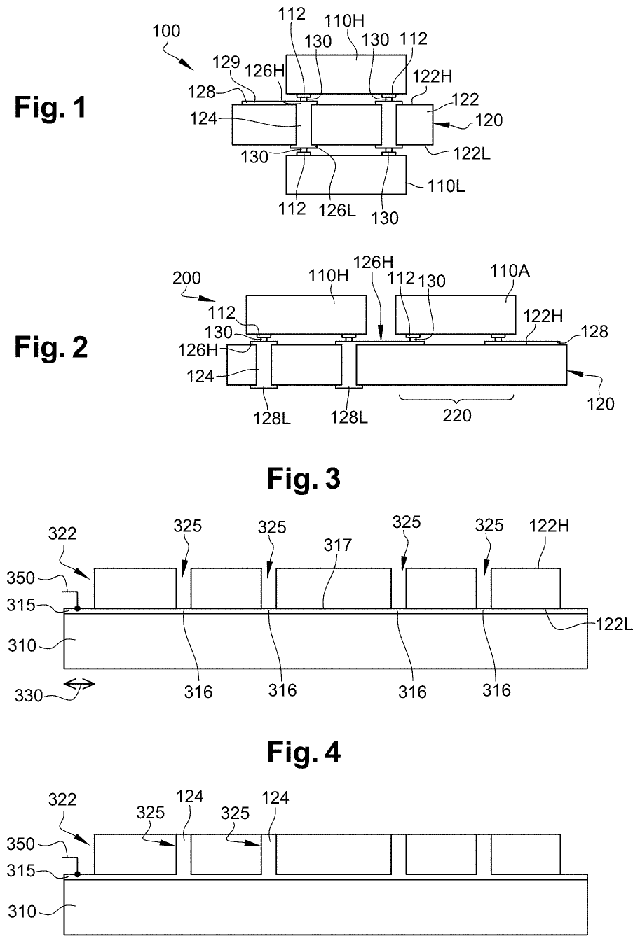

FIG. 1 is a simplified cross-section view showing an example of a device 100 to which the described embodiments apply.

Device 100 comprises two electronic chips 110H and 110L located on two opposite surfaces of a connection structure 120. Connection structure 120 interconnects circuits of the chips and ensures the mechanical hold of the chips.

Connection structure 120 comprises a substrate 122. Preferably, substrate 122 has the shape of a plate or of a wafer having two main opposite surfaces 122H and 122L. Substrate 122 is preferably a semiconductor wafer portion, for example, made of silicon. Substrate 122 may also be made of ceramic or, for example, of glass, or also may comprise an organic material such as epoxy resin, for example, a mixture of epoxy resin and glass fibers. More generally, the substrate may be any plate, wafer, or wafer portion having its two main surfaces capable of being at least partly covered with conductive elements.

Substrate 122 is crossed by vias 124. Preferably, vias 124 interconnect electrically-conductive regions 126L, 126H located on the opposite surfaces of substrate 122. Although two vias are shown as an example, connection structure 120 preferably comprises a number of vias greater than 2. Each of vias 124 is defined by a conductive element crossing substrate 122. Each via 124 electrically connects a conductive region 126L located on one of the opposite surfaces (122L) of the substrate to a conductive region 126H located on the other one of the opposite surfaces (122H) of the substrate. Conductive regions 126H and 126L are typically metal regions. Vias 124 may have the shape of cylinders, of rings, of concentric rings, or shapes filling rectilinear trenches (wall shapes). Vias 124 typically have shapes elongated in the substrate thickness direction, that is, each via has a larger dimension in the substrate thickness direction (longitudinal direction of the via) than in at least one transverse direction of the via.

Each chip 110H, 110L comprises connection pads 112. Connection pads 112 are intended to connect electronic circuits (not shown) of the chip to other circuits external to the chip. Such connection pads are typically metal regions located on the front side or on the back side of the chip.

The connection pads 112 of chips 110H and 110L are respectively connected to conductive regions 126H and 126L. More particularly, each connection pad 112 is in electric contact with one of conductive regions 126H and 126L, for example, via a solder or welding material 130 of by direct metal-to-metal bonding. For this purpose, the positions of conductive regions 126H and 126L correspond to those of connection pads 112. Further, material 130 mechanically fastens connection pads 112 to conductive regions 126H and 126L, which enables to ensure the mechanical hold of the chips on connection structure 120. In the shown example, the connection pads 112 of chips 110H and 110L are located in line with vias 124 (that is, above and under the vias), however, the chip connection pads are often not located in line with the vias.

Preferably, conductive regions 126H and/or 126L comprise one or a plurality of connection pads 128 and tracks 129 coupling connection pads 128 to vias 124. Although a single connection pad 128 has been shown, the connection structure preferably comprises a plurality of connection pads 128 located on one and/or the other of the opposite surfaces 122H and 122L of substrate 122. In an example, device 100 is intended to be arranged in a package provided with pins, and the connection pads 128 are intended to be connected to the pins. In another example, connection pads 128 are intended to connect device 100 to another device, not shown.

In a variant, connection structure 120 is formed by an electronic chip. The substrate is then preferably a semiconductor wafer portion, for example, made of silicon.

FIG. 2 is a simplified cross-section view showing another example of a device 200 to which the described embodiments apply.

The device 200 of FIG. 2 differs from the device 100 of FIG. 1 in that:
chip 110L is omitted and conductive regions 126L are replaced with connection pads 128L intended to be connected, for example, to the pins of a package;
a chip 110A is located on a portion 220 deprived of vias of connection structure 120, on the side of surface 122H; and
conductive regions 126H comprise tracks coupling the connection pads 112 of chip 110A to vias 124.

The devices 100 and 200 described hereabove in relation with FIGS. 1 and 2 are specific examples, and the embodiments described hereafter apply to any type of device comprising one or a plurality of chips connected to a connection structure 120 crossed by vias. More generally, the embodiments described hereafter apply to any device comprising a substrate such as substrate 122 crossed by conductive elements such as vias 124.

FIGS. 3 to 5 are simplified cross-section views showing steps of an embodiment of a method of manufacturing one or a plurality of conductive elements crossing a substrate 322.

Substrate 322 may be of the type of the substrate 122 described hereabove in relation with FIGS. 1 and 2. However, preferably, substrate 322 is a plate, more preferably a semiconductor wafer, intended to be cut into connection structures such as the structures 120 of FIGS. 1 and 2 and/or into individual chips and/or into any substrate of the type described in relation with FIGS. 1 and 2.

The conductive elements that the method enables to form are preferably vias of the type of the vias 124 of FIGS. 1 and 2, or form at least part of vias 124. More particularly, the described embodiments comprise a step of electrolytic deposition, or electrodeposition, of at least part of the conductive elements. The electrodeposited material is preferably copper, although the described embodiments also apply to any material currently used for the forming of vias and capable of being electrodeposited, such as nickel, nickel and iron alloys, gold, antimony, or silver.

At the step of FIG. 3, a stack is formed, which successively comprises (from bottom to top):
a support 310, typically plate-shaped;
a conductive seed layer 315, sometimes called nucleation layer, that is, a layer capable of forming a cathode on which the material of the conductive elements may be formed by electrodeposition; and
substrate 322, crossed by openings 325 located at the locations of the future conductive elements.

Support 310 is preferably of same nature as substrate 322, or support 310 has a thermal expansion coefficient identical or substantially identical to that of substrate 322. This enables to avoid various problems of deformation of the stack during subsequent steps of the method. Such problems would be likely to appear, for example, due to a rise in the temperature of the stack if the substrate and the support do not expand in the same way.

Openings 325 preferably extend orthogonally to the main surfaces 122H and 122L of substrate 322, in other words, the openings have a side located on the side of surface 122H and another side located on the side of surface 122L. Openings 325 are formed at the locations of the future conductive elements such as vias. Openings 325 preferably have a form factor greater than 10. The form factor of an element such as openings 325 or the vias is defined by the ratio of the dimension of the element in a longitudinal direction orthogonal to the main surfaces of the substrate to the smallest transverse dimension of the element.

In the stack, substrate 322 and openings 325 are located on a same side of seed layer 315. In other words, seed layer 315 has a surface 317, facing the substrate, capable of receiving the material of the conductive elements. More precisely, for each of openings 325, a portion 316 of the seed layer closes or seals the opening on the side of the substrate covered with the seed layer (surface 122L).

Preferably, layer 315 is a full layer, that is, comprising no openings, more preferably uniform, that is, of constant thickness. Each portion 316 then fully seals the corresponding opening 325. Layer 315 enables, as compared with a layer which would be discontinuous and/or non-uniform, to improve the adhesion of the layer and the subsequent filling of openings 325 by the electrodeposited material.

Preferably, seed layer 315 is planar, that is, portions 316 are located in line with seed layer 315. However, this is not limiting, and portions 316 may be located in any position in and/or facing (or vertically in line with) the opening, on the side of the opening facing the support. The seed layer is for example may be made of the same material as that which will be deposited. As an example, the seed layer is a copper layer having a thickness in the range from 100 nm to 2 μm.

The described embodiments are compatible with any method of forming a stack such as that of FIG. 3. Preferably, support 310 is previously covered with seed layer 315. Openings 325 may be formed before or after the placing of the substrate on the seed layer 315 covering support 310. Various embodiments of the stack of support 310, of seed layer 315, and of the substrate 322 crossed by openings 325 are described hereafter in relation with FIGS. 6 to 18.

Further, although the assembly of substrate 322 and of seed layer 315 is located on a support, this is not limiting, and support 310 may be omitted. However, the fact of providing support 310 previously covered with seed layer 315 eases (or allows, in the case where the substrate is too thin to be handled) the placing and the holding of the seed layer against openings 325 and surface 122L of the substrate, as compared with an embodiment where support 310 would be omitted.

Preferably, in a peripheral portion of the stack, support 310 and seed layer 315 laterally extend beyond substrate 322. In other words, a peripheral portion 330 of seed layer 315 and of support 310 protrudes around substrate 322. The surface facing substrate 322 of seed layer 315 is thus accessible or exposed in peripheral portion 330, that is, this surface is not covered with substrate 322. As an example, peripheral portion 330 has a width of approximately 5 mm. Preferably, the substrate and the support are two circular plates having different diameters. As an example, the substrate and the support are obtained from two identical circular plates, for example, semiconductor wafers such as silicon wafers, and a peripheral portion of the plate intended to form substrate 322 has been removed.

An electric connection 350 is formed in contact with seed layer 315 in peripheral portion 330. Electric connection 350 is provided to apply a cathode potential to the seed layer during the implementation of the electrodeposition. Although electric connection 350 is located on peripheral portion 350, this is not limiting, the described embodiments being compatible with any electric connection with seed layer 315. In particular, the peripheral portion may be omitted. However, the fact of providing electric connection 350 in the peripheral portion eases the arranging of the electric connection with respect to a device comprising no peripheral portion 330. The support, in particular, its size, is compatible with current electrodeposition equipment.

At the step of FIG. 4, the material of the conductive elements to be formed is deposited by electrodeposition in openings 325. Preferably, the openings are totally filled, which provides vias 124 crossing substrate 322. As a variant, only a portion of the openings is filled with the electrodeposited material, and the rest of the opening may be filled with another conductive material by any usual method.

The electrodeposition is performed by the passing of a current flowing from an anode to seed layer 315 through an electrolyte. The anode and the electrolyte are neither detailed nor shown, and the parameters of the electrolysis are not described herein, the described embodiments being compatible with usual electrodeposition methods. In particular, the described embodiments are compatible with current techniques used to improve the diffusion of chemical species in the electrolyte, such as stirring, the addition of an accelerating agent, etc.

Due to the fact that the seed layer covers at least part of surface 122L, and that the portions 316 of the seed layer closing openings 135 are located on the side of surface 122L, the current exclusively reaches the seed layer located at the bottom of openings 325. At the beginning of the deposition, the metal ions located in the electrolyte are attracted by portions 316 of the seed layer (taken to the cathode potential). Thus, the deposition increases from the bottom of the openings. In other words, the electrodeposition is performed from the portions 316 of the seed layer 315 sealing openings 325. In particular, as compared with a method that would use a seed layer covering upper surface 122H, the risk for the electrolytic deposition forming on surface 122H to close the openings before the complete filling is avoided. Form factors of the vias greater than 10, for example, greater than 20, can thus be simply obtained. In an example, the substrate has a thickness (corresponding to a via height) greater than 200 μm and the vias have widths smaller than 10 μm. In another example, the height of the vias is in the range from 100 to 400 μm and the vias have diameters in the range from 0.5 to 10 μm.

Increasing the form factor of the vias enables, for a given thickness of the substrate, to increase the number of vias per surface area unit of the substrate or, for a given number of vias per surface area unit, to increase the substrate thickness. Once can thus increase the number of vias and/or mechanically reinforce the substrate.

According to an advantage, the obtained vias are blind, that is, totally close openings 325. Such blind vias form better electric connections (that is, with a lower electric resistance) than vias which do not totally close the openings, for example, vias having their conductive material covering the walls of the openings but leaving a passage at the center of the openings.

According to another advantage, it can be done without a seed layer on the walls of openings 135. Various problems of deposition of this layer when the openings have high form factors, for example, greater than 10, are thus avoided. Further, the described embodiments are compatible with any method, conformal or non-conformal, of forming the seed layer on support 310. As an example, the seed layer is formed by chemical or physical vapor deposition CVD or PVD or by ionized physical vapor deposition IPVD. The forming of the seed layer is thus simpler than for a seed layer covering the inner walls of openings 135.

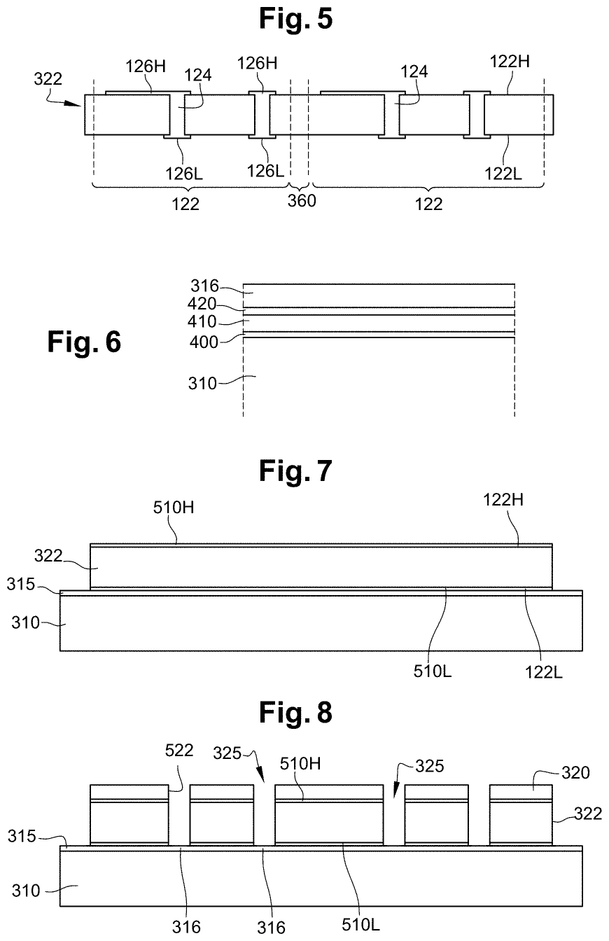

At the step of FIG. 5, conductive regions 126H, such as described in relation with FIG. 1, are formed on surface 122H of substrate 322. Conductive regions 126H are preferably formed on an insulator layer, not shown in FIG. 5, crossed by vias 124. Preferably, on each via 124, one of regions 126H covers the end of the via and extends on the substrate around the via. The described embodiments are compatible with usual methods of forming metal regions on the surfaces of a substrate.

Substrate 310 is then removed. Preferably, seed layer 315 remains on surface 122L of substrate 322. As a variant, substrate 310 is removed before the forming of conductive regions 126H.

Conductive regions 126L are then formed. As an example, conductive regions 126L, such as described in relation with FIG. 1, are formed on surface 122L. Preferably, conductive regions 126L are portions of seed layer 315 and of a possible additional conductive layer (not shown) deposited on layer 315 after the removal of support 310. As a variant, the additional layer is deposited on support 310 before forming seed layer 315. A portion of the seed layer and of the possible additional layer are removed, for example, by etching, so that the remaining portions form conductive regions 126L. Preferably, for each of vias 124, one of regions 126L covers the lower end of the via and extends on surface 122L of the substrate around the via, and/or one of regions 126H covers the upper end of the via and extends on surface 122H of the substrate around the via.

Apart from the fact, previously mentioned in relation with FIGS. 1 and 2, that conductive regions 126H and 126L enable to form conductive tracks and connection pads, conductive regions 126H and 126L extending on the substrate around the via enable to improve the mechanical resistance of the via in place in the corresponding opening 235. Thus, the vias are kept solidly fastened to the substrate. As a variant, the vias are solidly fastened to the substrate without providing regions 126H and 126L extending on the substrate around each via, for example, by adhesion in the openings.

As an example, at a subsequent step, substrate 322 is cut along cutting paths 360 to divide substrate 322 into individual substrates 122.

FIG. 6 is a partial simplified cross-section view showing an embodiment of support 310 covered with seed layer 315 such as described in relation with FIG. 3. More particularly, in this embodiment, additional layers 400, 410, and 420 are interposed, in this order from support 310, between support 310 and seed layer 315.

Additional layer 400 is electrically insulating, for example, layer 400 is a silicon oxide layer. Additional layer 400 is preferably in contact with support 310. In the case of an electrically-conductive or semiconductor support, for example, made of silicon, the presence of this layer eases the electrolytic deposition, by avoiding for support 310 to be taken to the cathode potential at the same time as the seed layer. However, layer 400 may be omitted, in particular in the case where support 310 is electrically insulating.

Additional layer 410 is capable of causing a lower adhesion of the seed layer to support 310 than to substrate 322. Layer 410 enables to remove the support at the step of FIG. 5 by exerting a separation force between the support and the substrate, to break layer 410 or separate it from layer 400 and/or from layer 420. In an embodiment, layer 410 is for example made of a thermoplastic-type polymer material, that is, temporary glue. The thickness of layer 410 is preferably of a few micrometers, for example, in the range from 5 μm to 10 μm. Layer 410 may be made of any material, for example, metallic, having a sufficiently low energy of adhesion to layer 400 to be able to separate layers 400 and 410 while leaving seed layer 315 on substrate 322. This is not limiting, the described embodiments are compatible with any mode of removal of support 310. Thus, in a variant, support 310 is removed by etching, and additional layer 410 is omitted or forms an etch stop layer.

As a variant, additional layers 400 and 410 are confounded, that is, additional layer 410, capable of easing the removal of support 310, forms an electric insulation layer.

Additional layer 420 is made of a material capable of easing the forming and/or the bonding of the seed layer on and/or to layer 410. Layer 420 is for example made of titanium or of titanium nitride. The thickness of layer 420 is for example in the range from 50 to 200 nm. As a variant, additional layer 420 is omitted.

FIGS. 7 to 9 are simplified cross-section views showing steps of a first embodiment of the step of FIG. 3. More particularly, in this embodiment, openings 325 are formed after the arranging of substrate 322 on support 310.

At the step of FIG. 7, substrate 322, for example, a silicon wafer, is arranged on seed layer 315 covering support 310. Preferably, surface 122L of the substrate has been previously covered with an electrically-insulating layer 510L, for example, made of silicon oxide. For such an arrangement, preferably, a polishing, for example, a chemical-mechanical polishing, of the surface of insulating layer 510L (or of substrate 322 in the absence of layer 510L) intended to be in contact with the seed layer and/or of the surface of the seed layer intended to be in contact with insulating layer 510L (or with substrate 322, surface 122L) is previously carried out. Preferably, the surface conditions of the surfaces thus polished provide an adhesion of molecular bonding type between the seed layer and insulating layer 510. The bonding is typically obtained by compression and heating.

Preferably, the obtained bonding is sufficient to be tight, in particular towards the electrolyte used at the step of FIG. 4, over at least 90% of the bonded surface. This is not limiting, and substrate 322 and seed layer 315 may, as a variant, be non-tightly assembled, for example, the substrate may be simply laid on the support. However, as compared with such a variant, the tight bonding enables to ease the steps, subsequent to the electrodeposition, of removal of the support and of forming of conductive regions on surface 122L from seed layer 315.

Preferably, surface 122H of the substrate is covered with an insulating layer 510H. Insulating layer 510H is for example formed at the same time as layer 510L, for example, by thermal oxidation. As a variant, the insulating layer is formed after the step of FIG. 8. In this variant, it may be provided to thin substrate 322 before the step of FIG. 8.

At the step of FIG. 8, a mask 520 crossed by openings 522 on the locations of the future openings 325 is formed by lithography. Openings 325 are then etched vertically in line with openings 522, from the upper surface of layer 510H to the level of the upper surface of seed layer 315, or to a level located in seed layer 315. Openings 325 cross upper insulating layer 510H, substrate 322, and insulating layer 510L. Seed layer 315 has exposed or accessible portions 316 located at the bottom of openings 325. The described embodiments are compatible with usual methods of directional etching of insulating and substrate layers.

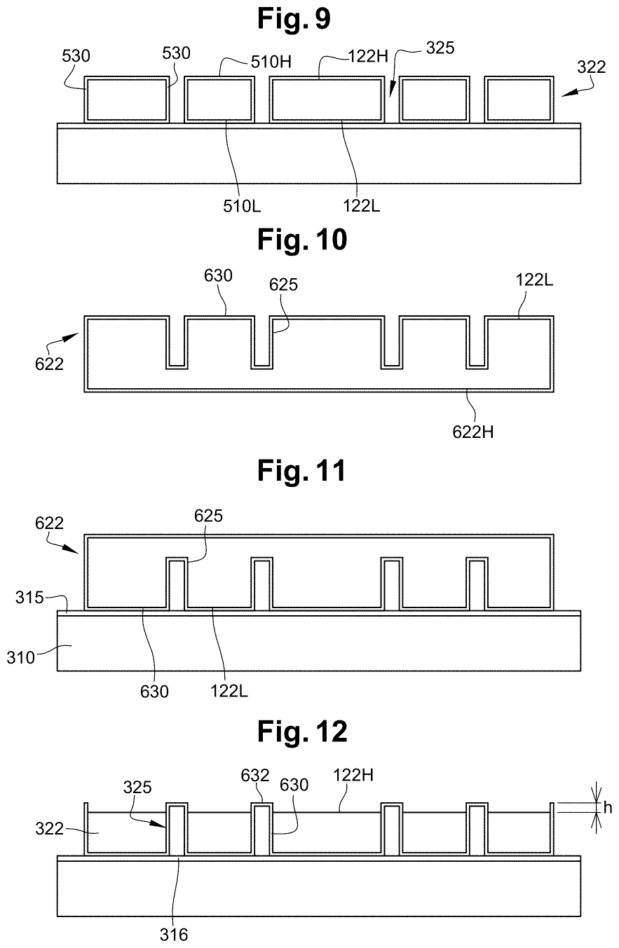

At the step of FIG. 9, mask 520 is removed. The walls of openings 325 are covered with a layer of electric insulator 530, for example, silicon oxide. Insulating layer 510H may be totally or partly formed at this step.

Insulating layer 530 enables to electrically insulate the substrate from the future vias formed in the openings. Further, the insulating layer enables to avoid for the material of the future vias to diffuse towards the substrate and to degrade the properties of the substrate material. Insulating layers 510L and 510H enable to obtain an electric insulation between the substrate and the future conductive regions 126L and 126H (FIG. 5) formed on its surfaces 122L and 122H.

According to a preferred embodiment, electric insulator 530 is conformally deposited, preferably by a CVD-type method. The thermal budget of such a deposition enables to provide an additional polymer layer, of the type of layer 410 (FIG. 6), located between support 310 and seed layer 315. Further, the thermal budget of such a deposition is compatible with substrate 322 in the case where the latter is intended to be cut into individual chips, substrate 322 then comprising elements of the electronic circuits of the chips. The embodiments described herein are compatible with usual methods of conformal deposition of an insulating layer.

FIGS. 10 to 14 are simplified cross-section views showing steps of a second embodiment of the step of FIG. 3. More particularly, openings 325 are formed partly before and partly after the arranging of substrate 322 on support 310.

At the step of FIG. 10, a wafer 622 where the future substrate 322 will be defined is provided, for example, a semiconductor wafer such as a silicon wafer.

One then forms, from a surface of the silicon wafer intended to form the future lower surface 122L of the future substrate (shown turned over), blind cavities 625, that is, cavities which do not emerge onto the surface (surface 622H) of wafer 622 opposite to surface 122L.

Preferably, a peripheral portion of wafer 622 (corresponding to portion 330 in FIG. 3) is removed. The removal may be performed before or after the forming of cavities 625.

After this, an insulating layer 630 covering all the surfaces of wafer 622, as well as the walls and the bottoms of the cavities, is formed. Preferably, insulating layer 630 is formed by thermal oxidation. Thermal oxidation has the advantage over a deposition method of easing the forming of the insulating layer on the walls of cavities having the high form factors defined hereabove, particularly on the walls of cavities having very high form factors, for example, greater than 15.

At the step of FIG. 11, wafer 622 is arranged on seed layer 315 covering support 310. The portion of layer 630 covering surface 122L is placed in contact with the seed layer. Such an arrangement is preferably performed similarly to what described in relation with FIG. 7. In particular, a molecular-type bonding is preferably performed after having performed a polishing of the surfaces to be bonded to each other. As an example, the distance between the bottom of cavities 625 and surface 622H is in the range from 5 to 50 μm, preferably from 10 to 20 μm. Such a distance is, in the shown example, obtained at the step of FIG. 10, however the distance is preferably obtained by a step, not shown, of thinning of wafer 622 on the side of its surface 622H.

At the step of FIG. 12, a portion of the wafer comprising the bottoms of the cavities is preferably removed by mechanical polishing. The remaining portion of the wafer forms substrate 322. Each of cavities 635 becomes an openings 325 crossing the substrate.

Preferably, the removal of the material of the wafer is selective over the material of insulating layer 630. Thus, a portion of insulating layer 630 initially covering the bottoms of cavities 625 is left in place at the removal step. Preferably, the removal is performed so that portions 632 of layer 630 initially located at the bottom of cavities 625 are located above the upper surface of the substrate (surface 122H). The level of surface 122H is preferably located at a height h of a few micrometers, for example, between 2 μm and 10 μm, under the lower level of portions 632 (that is, the level of the surfaces of portions 632 oriented towards openings 325).

As a variant, the portions 632 of layer 630 are also removed, and the structure allowing the electrolysis of the step of FIG. 4 is obtained. The removal is for example performed by chemical-mechanical polishing or by dry etching, to avoid damaging the portions of layer 630 covering the walls of openings 325 and/or the portions 316 of the seed layer located under openings 325.

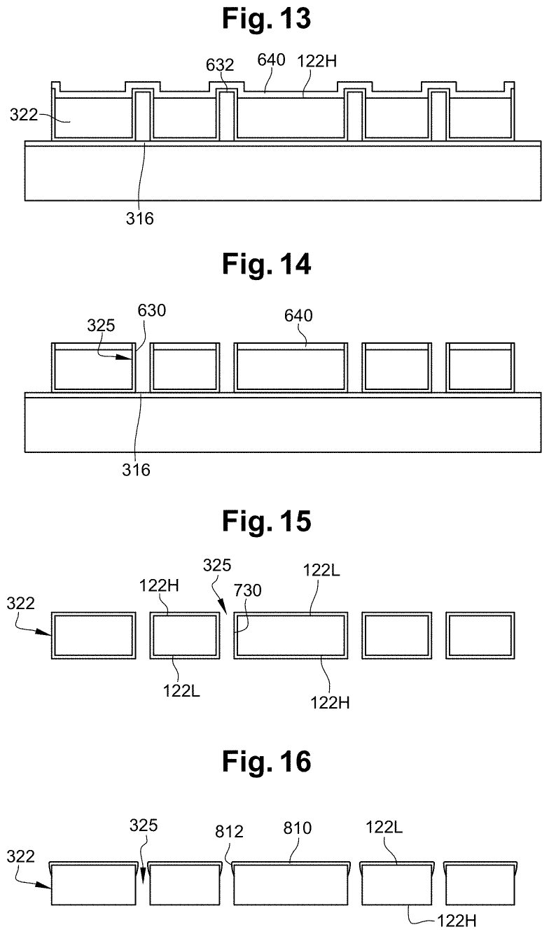

At the step of FIG. 13, another insulating layer (layer 640), for example, made of silicon oxide, is deposited on the upper surface 122H of the substrate. The portions of layer 632 enable to avoid for a portion of the material of layer 640 to be deposited in openings 325. Preferably, the thickness of layer 640 is smaller than height h between surface 122H and the lower level of portions 632.

At the step of FIG. 14, all the elements located above the upper level of layer 640 are removed, preferably by polishing. This removes portions 632 of insulating layer 630. The portions of layer 640 located on portion 632 are also removed. Level difference h thus enables to open openings 325 by polishing, while avoiding damaging the portions of layer 630 covering the walls of openings 325 and/or the portions 316 of the seed layer located under openings 325.

The structure obtained at the step of FIG. 14 may be used to perform the electrolysis described in relation with FIG. 4. The portions of layer 630 located on the walls of the openings enable to electrically insulate the vias or the conductive elements formed on the openings, and further enable to avoid the diffusion towards the substrate 322 of the material electrodeposited in openings 325.

The obtained layer 640 will enable, in the structure obtained at the step of FIG. 5, to obtain an electric insulation between conductive regions 126H (FIG. 5) and substrate 322.

FIG. 15 is a simplified cross-section view showing a third embodiment of the step of FIG. 3. More particularly, openings 325 are formed before the arranging of substrate 322 on seed layer 315 covering support 310 (support and seed layer not shown in FIG. 15).

At the step of FIG. 15, openings 325 are formed in substrate 322. The substrate is preferably defined by a semiconductor wafer portion, for example, made of silicon. This embodiment is compatible with any usual way of forming openings in a substrate, such as a chemical or plasma etching, a laser machining, a mechanical machining, a machining by pressurized water, etc.

An insulating layer 730 covering all the surfaces of substrate 322 and in particular the walls of openings 325 is then formed. Insulating layer 730 is preferably obtained by thermal oxidation, for example at a temperature in the order of 1,000° C. As mentioned, the thermal oxidation enables to form the insulating layer on the walls of openings having high form factors more easily than conformal deposition methods.

In a variant, an insulating layer is formed on upper surface 122H and/or an insulating layer is formed on lower surface 122L prior to the forming of openings 325. The insulating layer(s) are then crossed by the openings. The presence of this layer enables to limit the oxide growth on surfaces 122H and 122L during the thermal oxidation.

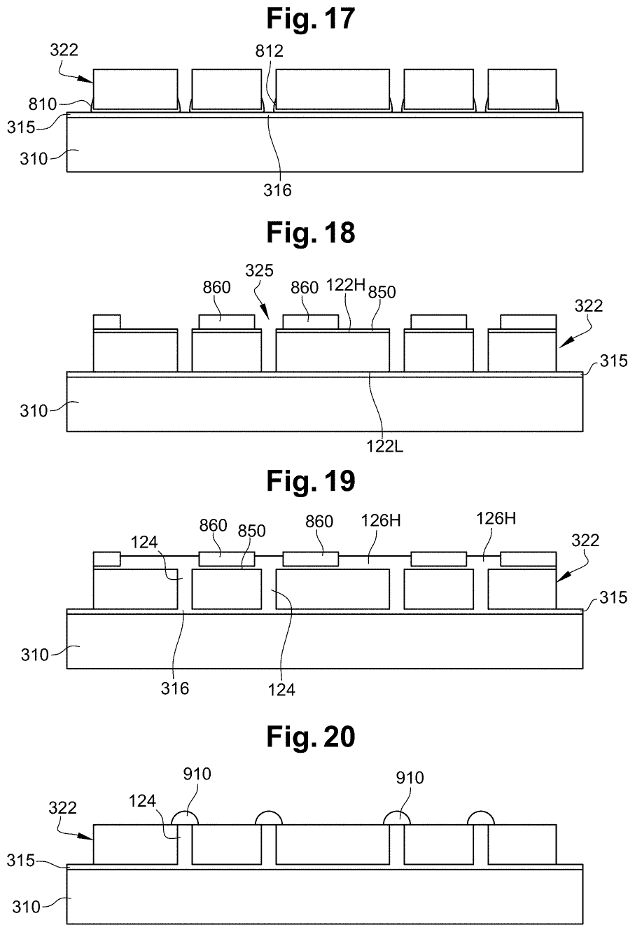

FIGS. 16 and 17 are simplified cross-section views showing steps of a fourth embodiment of the step of FIG. 3.

At the step of FIG. 16, openings 325 crossing substrate 322 are formed. A conductive layer 810 is then formed on surface 122L of the substrate (surface intended to be covered with seed layer 135). Conductive layer 810 is deposited so that a portion 812 of layer 810 covers a portion of the walls of openings 325 on the side of surface 122L. This may be obtained by an incompletely uniform deposition, where the deposited material does not reach the portions of openings 325 most distant from surface 122L, in particular due to a high form factor of openings 325.

At the step of FIG. 17, the substrate is arranged on support 310. More particularly, layer 810 and seed layer 315 are placed in contact with each other, preferably by molecular-type bonding.

Preferably, layer 810 is made of the same material as the seed layer, or of another material on which the electrolytic deposition may be performed. Metal layer 810 thus forms an additional seed layer. The portions 812 of seed layer 810 are in contact with the portions 316 of seed layer 315 and enable to ease the initiation of the electrolytic deposition with respect to an electrodeposition performed without portions 812.

Preferably, layer 810 is formed on a bonding layer, not shown, for example, made of titanium or of titanium nitride. The bonding layer provides a better adhesion of the metal, for example, copper, of layer 810. This enables to ensure the mechanical hold between the future via and substrate 322. Further, the bonding layer may have barrier properties enabling to avoid the diffusion of the electrodeposited material towards the substrate, and thus enables to avoid for the material of the substrate to be altered by the diffusion.

This embodiment can be combined with the embodiments where the openings or cavities are formed, or partially formed, before the arranging of the substrate on the support, for example, the embodiment of FIGS. 10 to 14 or that of FIG. 15.

As a variant, layer 810 entirely covers the walls of openings 325.

FIG. 18 is a simplified cross-section view showing a step of a fifth embodiment of the step of FIG. 3. FIG. 19 is a simplified cross-section view showing a step similar to that of FIG. 4 after the implementation of the fifth embodiment.

At the step of FIG. 18, another seed layer (layer 850) is formed on upper surface 122H of the substrate. Preferably, seed layer 850 is formed after the forming of openings 325. Seed layer 850 may then, according to the conformity of the deposition, cover substrate 322 only around the openings or also cover at least part of the walls of the openings. Insulating portions 860 are then formed on layer 850. Insulating portions 860 are preferably formed at the locations of surface 122H which will be, after the implementation of the step of FIG. 5, deprived of conductive regions 126H. As an example, a resist layer, for example, made of dry film resist DFR, is formed so that the resist does not penetrate into cavities 325. The resist portions at the locations of the future conductive regions 126H are then removed by lithography. The remaining portions of the resist layer form insulating portions 860.

At the step of FIG. 19, vias 124 are formed by electrodeposition. At the end of the forming of vias 124, the latter form an electric contact with seed layer 850, and the deposition carries on, on all the seed layer portions which are not covered with portions 860. The portions thus deposited will form conductive regions 126H after the removal, at the step of FIG. 5, of the portions of seed layer 850 located under portions 860.

As long as the vias being formed have not reached seed layer 850, the deposit only forms from the portions 316 of seed layer 310 (from the bottom of the openings). Vias 124 and conductive regions 126H can thus be formed during a same electrolysis step, which simplifies the manufacturing method while benefiting from the above-mentioned advantages, in particular the advantage of forming vias having high form factors without risking closing the upper portions of the cavities before having completely formed the vias.

In an alternative embodiment, portions 860 are omitted. The electrodeposition is then performed over the entire surface of layer 850. At the step of FIG. 5, the portions of layer 850 located outside of conductive regions 126H are then etched.

The present embodiment is compatible with the previous embodiments, that is, substrate 322 may correspond to the substrate obtained in the embodiments of FIGS. 7 to 9, of FIGS. 10 to 14, of FIG. 15, and/or of FIGS. 16 and 17. In particular, seed layer 850 may be formed on an insulating layer such as layer 510H (FIG. 9), 640 (FIG. 14), or 730 (FIG. 15).

FIG. 20 is a simplified cross-section view showing a variant of the step of FIG. 5. In this variant, a solder pad 910 is formed by electrodeposition on each of vias 124. For this purpose, the electrodeposition of the material of the vias is continued by the electrodeposition, preferably, of a fusible alloy, for example, a tin-based alloy. The alloy is then only deposited on the tops of vias 124. This step may be followed by a melting step enabling to give connection pads 910 the shape of bumps. This embodiment is compatible with those of FIGS. 7 to 9, 10 to 14, 15, and/or 16 and 17.

Various embodiments and variants have been described. Those skilled in the art will understand that certain features of these embodiments can be combined and other variants will readily occur to those skilled in the art.

Finally, the practical implementation of the described embodiments and variations is within the abilities of those skilled in the art based on the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method of manufacturing at least one element crossing a substrate, comprising a step of electrodeposition of at least part of said element in an opening crossing the substrate and on a portion of a conductive seed layer located on at least part of a surface of the substrate, said portion of the seed layer being located on a same side of the opening as said surface of the substrate.

2. The method according to claim 1, wherein the openings have a form factor greater than 10.

3. The method according to claim 1, wherein the substrate is assembled on a support and the conductive seed layer is located between the substrate and the support.

4. The method according to claim 3, wherein a first additional layer located between the support and the seed layer is capable of causing a lower adhesion of the seed layer to the support than to the substrate.

5. The method according to claim 3, wherein a first additional etch stop layer of the support is located between the support and the seed layer.

6. The method according to claim 4, wherein a second additional bonding layer of the seed layer is located between the seed later and the first additional layer.

7. The method according to claim 3, wherein the seed layer and the support are separated by an electric insulator.

8. The method according to claim 3, wherein the support and the seed layer extend laterally beyond the substrate.

9. The method according to claim 1, wherein the walls of the opening are covered with an insulating layer.

10. The method according to claim 9, wherein said insulating layer is formed by thermal oxidation.

11. The method according to claim 9, comprising a step of forming of blind cavities in a wafer comprising the future substrate, and a step of removal of a portion of the wafer comprising the bottoms of the cavities.

12. The method according to claim 11, wherein a portion of said insulating layer covering said bottoms of the cavities is left in place at the removal step, another insulating layer is deposited on another surface of the substrate opposite to said surface, and said portion is then removed.

13. The method according to claim 1, wherein an additional seed layer in contact with said seed layer covers at least part of the walls of the openings.

14. The method according to claim 1, comprising a step of forming another seed layer on said other insulating layer or on another surface of the substrate opposite to said surface.

15. The method according to any of claim 1, wherein the electrodeposition step comprises the forming of a solder bump on the crossing element.
